(19) United States
(12) Patent Application Publication
(10) Pub. No.: US 2021/0091711 A1
(43) Pub. Date: Mar. 25, 2021

(54) SOLAR PANEL FOR INDUSTRIAL ROOFS AND A ROOF WHEREIN THIS SOLAR PANEL IS APPLIED

(71) Applicant: Mehmet Nazim YAVUZ, Istanbul (TR)

(72) Inventor: Mehmet Nazim YAVUZ, Istanbul (TR)

(21) Appl. No.: 16/967,459

(22) PCT Filed: Feb. 6, 2019
(86) PCT No.: PCT/TR2019/050072

§ 371 Date: Aug. 5, 2020

(30) Foreign Application Priority Data
Feb. 12, 2018 (TR) 2018/01945

(51) Int. Cl. H02S 20/23; H01L 31/049

(52) U.S. Cl. CPC H02S 20/23; H01L 31/049

(57) ABSTRACT

This invention is related to a solar panel composed of a membrane as a base layer, wherein the base layer is to be integrated to an industrial roof, and from the bottom to the uppermost respectively: a lowermost protection layer on this membrane; electrical isolation back sheet on this lowermost protection layer; a lower protection layer on this electrical isolation back sheet; a solar cell layer on this lower protection layer; an upper protection layer on this solar cell layer; and a front face protection layer on this upper protection layer; and related to an industrial roof comprising such solar panel.

### CROSS REFERENCE TO THE RELATED APPLICATIONS

This application is the national stage entry of International Application No. PCT/TR2019/050072, filed on Feb. 6, 2019, which is based upon and claims priority to Turkish Patent Application No. 2018/01945, filed on Feb. 12, 2018, the entire contents of which are incorporated herein by reference.

### TECHNICAL FIELD

This invention is related to a solar panel for industrial roofs like house, fabric, plaza, school roofs and to a roof wherein this solar panel is applied.

### BACKGROUND

Nowadays, solar energy systems and solar panels therefor become undeniably crucial to diversify the energy sources. Solar panel is an energy source and includes several solar cells for absorbing solar energy.

However, load carrying capacity of the current industrial roofs is weak. For this reason, as the weight of solar power systems and solar panels to be applied on a roof is heavy, montage of the solar power systems and solar panels on these roofs is quite difficult. Drilling into or overloading these roofs causes collapsing of the roofs. Mounting of more than one person on these roofs also results in increasing of weight in addition to the solar panel's weight on the roofs. This makes it impossible to constitute a roof comprising solar panels which works efficiently.

Furthermore, in the state of the art, solar panel setups of the industrial roofs have been performed via drilling into the roof in one way or another that destroys the roof integrity. This also causes disruption of the water and heat insulation of the roof.

### SUMMARY

The aim of the invention is to realize a solar panel that will not harm water and heat insulation of the industrial roofs like home, school, hospital, plaza, fabric, warehouse roofs and will support such insulation.

Another aim of this invention is to realize a solar panel that is light enough to allow installation by a single person.

Another aim of this invention is, to realize a solar panel of which the production can be done practically and which can be installed to the roof practically.

The solar panel subject to the invention consists of a membrane as a base layer wherein the base layer is to be integrated to an industrial roof; from the bottom to the top respectively: a lowermost protection layer on this membrane; electrical isolation back sheet on this lowermost protection layer; a lower protection layer on this electrical isolation back sheet; a solar cell layer, having solar cells that provide electricity production, on this lower protection layer; an upper protection layer on this solar cell layer; and a front face protection layer on this upper protection layer. Solar panel subject to invention also comprises a junction unit.

Main layers in the solar panel are membrane, back sheet, solar cell layer and front face protection layer. Between these main layers are upper, lower and lowermost protection layer that are made of EVA material.

Each of the upper, lower and lowermost protection layers is an EVA (Ethylene Vinyl Acetate) membrane.

Front face protection layer is a tempered glass.

Membrane comprises a TPO thermoplastic polyolefin and/or PVC Polyvinyl Chloride.

The junction unit is placed in such a way that it does not prevent the membrane's lower surface from being laminated to the roof.

In one embodiment of the invention, the junction unit is positioned on the back sheet. Back sheet comprises a protrusion for positioning of the junction unit. In an alternative of this embodiment of the invention, this protrusion overhangs from one short side (i.e. edge) of the back sheet. In these embodiments, the junction unit is positioned on the protrusion.

In another embodiment of the invention, the junction unit is positioned on the front face protection layer.

Surface area of the membrane is bigger than the surface area of the front face protection layer, upper protection layer, solar cell layer, lower protection layer, back sheet and lowermost protection layer.

The front face protection layer has a surface area in a size that covers the surface area of the solar cell layer.

Back sheet has a surface area, which is more than the surface of the front face protection layer and solar cell layer and less than the surface area of the membrane.

The upper, lower and lowermost protection layers have a surface area equal to each other in such a way that provides sealing of the main layers to each other and more than the surface of the front face protection layer in such a manner that allows the protection layers to protrude out of the front face protection layer's surface in a predetermined amount.

In an embodiment of the invention, the sides of upper, lower and lowermost protection layers are dimensioned such that each of the sides protrudes out of a corresponding front face protection layer's side approximately 2 cm.

The ratio of a long side of the front face protection layer to a long side of the membrane is a number between 0.6 to 1 or equal to one of these numbers.

The ratio of a short side of the front face protection layer to a short side of the membrane is a number between 0.5 to 1 or equal to one of these numbers.

The ratio of the distance between a short or long side length of the membrane and a short or long side of the front face protection layer to the short or long side's length of the membrane is a number between 0 to 1 or equal to one of these numbers.

In an embodiment of the invention, long side of the front face protection layer is approximately 16 cm and short side is approximately 10 cm and long side of the membrane is approximately 18 cm and short side is approximately 12 cm.

The invention comprises additionally a roof or roof system comprising a solar panel as described above. Such solar panel is fixed to the roof via a lamination process between a membrane of the solar panel and a membrane which is the uppermost layer of the roof.

Industrial roof used in the scope of the invention is an inclined roof or a bowless roof wherein its uppermost layer comprises a synthetic membrane and/or a sandwich panel and/or a trapeze plate.

### BRIEF DESCRIPTION OF THE DRAWINGS

FIG. 1: In an embodiment of the invention, top view of the solar panel wherein its layers are sealed to each other.

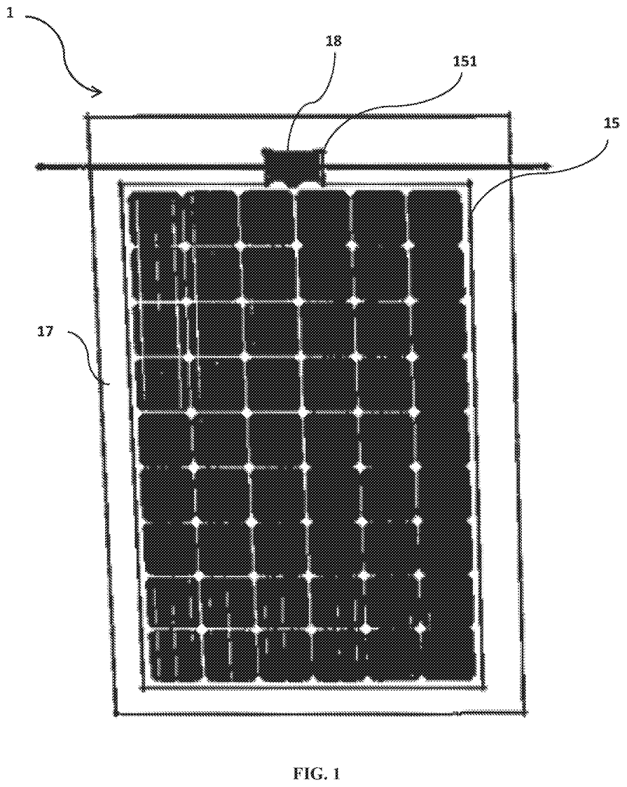

FIG. 2: Exploded view of the solar panel, in the invention's embodiment of FIG. 1.

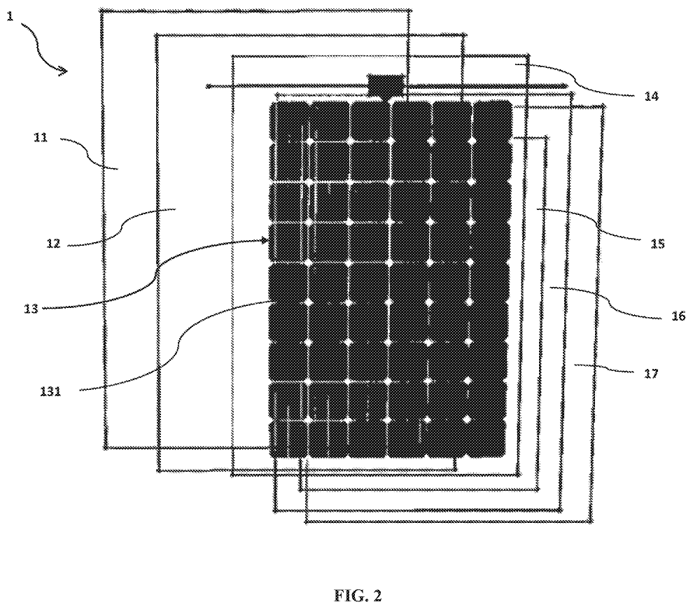

### DESCRIPTION OF THE REFERENCES IN THE FIGURES

2. Solar panel
11. Front face protection layer
12. Upper protection layer
13. Solar cell layer
131. Solar cell
14. Lower protection layer
15. Back sheet
151. Protrusion
16. Lowermost protection layer
17. Membrane
18. Junction unit

### DETAILED DESCRIPTION OF THE EMBODIMENTS

Solar panel (1) subject to the present invention comprises: a membrane (17) as a base layer wherein the base layer is to be integrated to an industrial roof, and from the bottom to the uppermost respectively: a lowermost protection layer (16) on this membrane (17); electrical isolation back sheet (15) on this lowermost protection layer (16); a lower protection layer (14) on this electrical isolation back sheet (15); a solar cell layer (13) on this lower protection layer (14); an upper protection layer (12) on this solar cell layer (13); and a front face protection layer (11) on this upper protection layer (12).

The solar panel (1) subject to the present invention does not comprise any other layer between these above cited layers (i.e. 11, 12, 13, 14, 15, 16, 17). Therefore, the weight of the solar panel is decreased and a very lightweight panel is realized.

In the solar panel (1) subject to the present invention, main layers are; membrane (17), back sheet (15), solar cell layer (13) and front face protection layer (11). Between these main layers, interlayers, i.e, upper, lower and lowermost protection layers (12, 14, 16), are provided.

Solar cell layer (13) comprises solar (i.e. photovoltaic) cells (131) that provide electricity production.

The solar panel (1) subject to the present invention also comprises a junction unit (18). This unit (18) provides solar cell layer (13) of the solar panel (1) to produce electrical output wherein the solar cell layer (13) is composed of serial or parallel connected solar cells (131).

Front face protection layer (11) is a tempered glass, namely a heat treated glass.

Upper, lower and lowermost protection layers (12, 14 and 16) are each EVA (Ethylene Vinyl Acetate) membrane. Such protection layers (12, 14 and 16) are commercially known in the market as “encapsulate EVA” which is a layer that is covered to lower and upper parts of the classical solar cell (131).

Back sheet (15) is an electrical isolation layer.

Membrane (17) which takes part at the bottom of the solar panel and will be mounted on the roof, comprises a TPO thermoplastic polyolefin and/or PVC Polyvinyl Chloride.

Solar panel (1) subject to the present invention, is fixed directly to a membrane layer which takes part at the uppermost place of the industrial roof, via the membrane (17) at the lowermost place of the solar panel (1). Fixing process is performed by bonding via heating, namely lamination.

Junction unit (18), is a unit that collects the energy that arrives from solar cells. Preferably this unit is a junction box. Junction unit (18), is positioned in such a way that it does not prevent the lower surface of the membrane (17) from being laminated to the roof, namely, in a position that it will not touch this surface. Junction unit (18) is preferably positioned on the back sheet (15).

In the present invention, size of the membrane (17), namely surface area of the membrane (17), is greater than all other layers (11, 12, 13, 14, 15, 16). The size of the front face protection layer (11) is in a size, that is enough to cover the size of the solar cell layer (13). The size of the back sheet (15), is greater than the surface area of the front face protection layer (11) and solar cell layer (13) and less than the surface area of the membrane (17). Back sheet (15) comprises a protrusion (151) for positioning of the junction unit (18). This protrusion (151) overhangs from the short edge of the back sheet (15) in one embodiment of the invention.

Upper, lower and lowermost protection layers (12, 14 and 16), have sizes equal to each other whereby these sizes, namely surface areas are greater than the surface area of the front face protection layer (II) in such a manner that they overhang from this surface area by a predetermined amount. By this means, impermeability function is gained to solar panel (1). By means of overhanging upper, lower and lowermost protection layers (12, 14 and 16) from front face protection layer's (11) edges (i.e. sides), sealing of layers between front face protection layer (11) and membrane (17) is provided. Thus, all main layers (11, 13, 15, 17) are sealed to each other, including membrane (17) and front face protection layer (11). Therefore, entering of water between membrane (17) and front face protection layer (11) and delamination of the panel (1) are prevented during commercial lifetime of the solar panel (1), (minimum for 25 years). According to the test results, solar panel (1) can produce electricity efficiently at least 25 years by this method.

In a preferred embodiment of the present invention, the sides of upper, lower and lowermost protection layers (12, 14 and 16) are dimensioned such that the cited sides protrude out of the front face protection layer's (11) sides 2 cm each.

In the present invention, layers have preferably rectangular surface areas.

In the present invention, the length ratio of a long side of the front face protection layer (11) to a long side of the membrane (17) is between 0.6 to 1 or equal to one of these numbers:

0.6≤long side of the front face protection layer (11)/long side of the membrane (17)≤1

The length ratio of a short side of the front face protection layer (11) to a short side of the membrane (17) is between 0.5 to 1 or equal to one of these numbers:

0.5≤short side of the front face protection layer (11)/short side of the membrane (17)≤1 The ratio of the distance between a short side of the membrane (17) and a short side of the front face protection layer (11) to the length of the cited short side of the membrane (17) is between 0 to 1 or equal to one of these numbers.

The ratio of the distance between a long side (i.e. edge) of the membrane (17) and a long side (i.e. edge) of the front face protection layer (11) to the length of the cited long side of the membrane (17) is between 0 to 1 or equal to one of these numbers:

0≤the distance between one long side of the membrane (17) and one long side of the front face protection layer (11) which is on the same side (i.e. part) as the cited long side of the membrane (17)/length of the cited long side of the membrane (17)≤1

When the distance between membrane (17) and front face protection layer (11) is large, solar efficiency of the solar panel (1) mounted roof decreases; and if the distance is small, the efficiency increases but montage of the solar panel (1) to the roof gets harder. In the second case, the montage gets more difficult because the size of the front face protection layer (11) increases and thereby the weight also increases. Therefore, the above cited ratios are optimum ratios, whereby panel (1) is mounted easily, the production is the most practical while the efficiency does not decrease.

In one embodiment of the invention, the long side of the front face protection layer (11) is approximately 1600 mm and the short side of the front face protection layer (11) is approximately 998 mm. In this embodiment, the long side of the membrane (17) is approximately 1840 mm and the short side of the membrane (17) is approximately 1138 mm. In this embodiment, when we place the solar panel (1) in front of us, the distance between the membrane and the glass, wherein the distance remains at the top (i.e. at the side of junction unit (18)), is approximately 170 mm.

Solar panel (1) subject to the invention provides electrical isolation conditions according to the standard of IEC61215-1. This panel (1) isolates electrically voltage of 1000 Volts.

When solar panel (1) subject to the present invention is montaged to an industrial roof, it constitutes an integrated system with the roof. Panel (1) sticks to the roof totally and therefore, it integrates with the roof. Thanks to this, the sustainability of the insulation is provided and panel is not effected from natural events like wind and storm.

In the present invention, thanks to the alignment, structure and contents of the layers, panel (1) is lightened and rendered to a construction such that a single person can easily perform roof installation (montage).

As panel (1) subject to the present invention is suitable for the lamination process to be applied to the roof, breakdown of the roof insulation is also prevented. Therefore, the integrity of the roof is not damaged. Due to the structure as described above and the installation via lamination, this panel (1) combines with the insulation and also increases the roof insulation.

The invention is not limited by the disclosed embodiments above, a skilled person in the art can produce different embodiments of the invention easily. The embodiments should be evaluated within the scope of invention protection demanded with claims.

What is claimed is:

1. A solar panel comprising a membrane as a base layer wherein the base layer is to be integrated to an industrial roof, and from the bottom to the uppermost respectively: a lowermost protection layer on the membrane; an electrical isolation back sheet on the lowermost protection layer; a lower protection layer on the electrical isolation back sheet; a solar cell layer having solar cells providing electricity production, on the lower protection layer; an upper protection layer on the solar cell layer; and a front face protection layer on this upper protection layer; and the solar panel further comprises a junction unit providing the solar cell layer to produce electrical output; wherein surface areas of the upper protection layer, the lower protection layer, and the lowermost protection layer are equal to each other; and the surface areas of the upper protection layer, the lower protection layer, and the lowermost protection layer are each greater than a surface area of the front face protection layer in such a manner that the surface areas of the upper protection layer, the lower protection layer, and the lowermost protection layer each overhang from the surface area of the front face protection layer by a predetermined amount.

2. The solar panel according to claim 1, wherein the upper protection layer, the lower protection layer and the lowermost protection layer are each EVA (Ethylene Vinyl Acetate) membrane.

3. The solar panel according to claim 1, wherein the front face protection layer is a tempered glass.

4. The solar panel according to claim 1, wherein a material of the membrane comprises a TPO thermoplastic polyolefin and/or PVC Polyvinyl Chloride.

5. The solar panel according to claim 1, wherein the junction unit is placed in such away that the junction unit does not prevent a lower surface of the membrane from being laminated to the industrial roof.

6. The solar panel according to claim 5, wherein, the junction unit is positioned on the electrical isolation back sheet.

7. The solar panel according to claim 6, wherein the electrical isolation back sheet comprises a protrusion for positioning of the junction unit.

8. The solar panel according to claim 7, wherein the protrusion overhangs from a short side of the electrical isolation back sheet.

9. The solar panel according to claim 7, wherein the junction unit is positioned on the protrusion.

10. The solar panel according to claim 5, wherein the junction unit is positioned on the front face protection layer.

11. The solar panel according to claim 1, wherein a surface area of the membrane is greater than the surface area of the front face protection layer, the surface areas of the upper protection layer the lower protection layer, and the lowermost protection layer, a surface area of the solar cell layer, and a surface area of the electrical isolation back sheet.

12. The solar panel according to claim 1, wherein a size of the surface area of the front face protection layer is sufficient for the surface area of the front face protection layer to cover a surface area of the solar cell layer.

13. The solar panel according to claim 1, wherein a surface area of the electrical isolation back sheet is greater than the surface area of the front face protection layer and a surface area of the solar cell layer and less than a surface area of the membrane.

14. (canceled)

15. The solar panel according to claim 1, wherein sides of the upper protection layer, the lower protection layer and the lowermost protection layer are dimensioned so as to each protrude out of a corresponding side of the front face protection layer by approximately 2 cm.

16. The solar panel according to claim 1, wherein a ratio of a long side of the front face protection layer to a long side of the membrane is from 0.6 to 1.

17. The solar panel according to claim 1, wherein a ratio of a short side of the front face protection layer to a short side of the membrane is from 0.5 to 1.

18. The solar panel according to claim 1, wherein a ratio of a distance between a short or long side of the membrane and a corresponding short or long side of the front face protection layer to a length of the corresponding short or long side of the membrane is from 0 to 1.

19. The solar panel according to claim 1, wherein long side of the front face protection layer is approximately 16 cm and a short side of the front face protection layer is approximately 10 cm, and a long side of the membrane is approximately 18 cm and a short side of the membrane is approximately 12 cm.

20. (canceled)

21. (canceled)

22. The solar panel according to claim 2, wherein the front face protection layer is a tempered glass.

23. The solar panel according to claim 2, wherein a material of the membrane comprises a TPO thermoplastic polyolefin and/or PVC Polyvinyl Chloride.
